(19) United States
(12) Patent Application Publication
(10) Pub. No.: US 2022/0102171 A1
(43) Pub. Date: Mar. 31, 2022

(54) SUBSTRATE TREATING APPARATUS

(71) Applicant: SEMES CO., LTD., Cheonan-si (KR)

(72) Inventors: Jae Oh BANG, Seoul (KR); Jong Gun LEE, Yeosu-si (KR)

(73) Assignee: SEMES CO., LTD., Cheonan-si (KR)

(21) Appl. No.: 17/486,238

(22) Filed: Sep. 27, 2021

(30) Foreign Application Priority Data
Sep. 29, 2020 (KR) 10-2020-0127288

(51) Int. Cl. H01L 21/67; H01L 21/683

(52) U.S. Cl. CPC H01L 21/67103; H01L 21/683

(57) ABSTRACT

The inventive concept provides a substrate treating apparatus. In an embodiment, the substrate treating apparatus includes a process chamber having a treatment space, a support unit that supports a substrate in the treatment space, and a supply line that supplies a process gas into the treatment space, and the support unit includes a heating plate provided with a heater pattern on a lower surface thereof and that heats the supported substrate, and an insulation layer covering the heater pattern and the lower surface of the heating plate.

### CROSS-REFERENCE TO RELATED APPLICATIONS

A claim for priority under 35 U.S.C. § 119 is made to Korean Patent Application No. 10-2020-0127288 filed on Sep. 29, 2020, in the Korean Intellectual Property Office, the entire contents of which are hereby incorporated by reference.

### BACKGROUND

The inventive concept relates to a substrate treating apparatus, and more particularly, to an apparatus for heating a substrate.

Various processes such as photographing, etching, deposition, and cleaning are performed to manufacture a semiconductor device. The photographing process is a process for forming patterns, and plays an important role in high integration of semiconductor devices.

The photographing process largely includes an application process, an exposure process, and a development process, and a baking process is performed in operation before and after the exposure process is performed. The baking process is a process of transferring heat to a substrate to heat-treat the substrate. In the baking process, after a substrate is positioned on a heating plate, a heating member provided in the heating plate transfers heat to the substrate to heat-treat the substrate.

In recent years, for fineness of line widths, introduction of photoresist including a metallic material such as a metal oxide, which is not based on a chemical material such as acrylate, or styrene, has been tried. Mist is supplied into a process chamber as a process gas to manage humidity in a process of baking photoresist, and the inventors recognized that an insulation layer including a material such as epoxy formed on a heater pattern constituting a heating unit absorbs moisture and influences heater patterns as the humidify in an interior of the process chamber increases due to the supplied mist. In particular, paste used for manufacturing a metallic pattern is based on Ag and is vulnerable to ion migration, and there is a high possibility of generating a defect due to an electrochemical migration (ECM).

### SUMMARY

Embodiments of the inventive concept provide a substrate treating apparatus that may efficiently treat a substrate.

Embodiments of the inventive concept also provide a substrate treating apparatus that may prevent an ECM due to a humid environment.

Embodiments of the inventive concept also provide a substrate treating apparatus that includes a heating unit including a support unit, in which bases may obtain excellent mechanical characteristics with a set thickness.

Embodiments of the inventive concept also provide a substrate treating apparatus that may minimize a heating plate from being deflected due to heat.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a process chamber having a treatment space, a support unit that supports a substrate in the treatment space, and a supply line that supplies a process gas into the treatment space, and the support unit includes a heating plate provided with a heater pattern on a lower surface thereof and that heats the supported substrate, and an insulation layer covering the heater pattern and the lower surface of the heating plate.

The process gas may include moisture.

The insulation layer may be formed of a material including a thermosetting resin.

The thermosetting resin may include epoxy.

The insulation layer may be formed of an epoxy molding compound.

The epoxy molding compound may include with respect to a total of 100 wt %, an inorganic filter of 65 to 88 wt %, an epoxy resin of 7 to 30 wt %, an epoxy resin hardener of 2 to 13 wt %, and an additive of 1.25 to 3 wt %.

The epoxy molding compound may include, with respect to a total of 100 wt %, an inorganic filler of 65 to 88 wt %, and the inorganic filler has particles of sizes of 2 to 30 μm, and has, with respect to the inorganic filler of 100 wt %, 20 to 35 wt % of particles having an average particle diameter of 5 μm or less and 65 to 80 wt % of particles having an average particle diameter of more than 5 μm.

In the inorganic filler, the particles of the average diameter of 5 μm or less may have spherical shapes, and the particles of the average diameter of more than 5 μm may have irregular shapes.

The heating plate may have a thickness of 1 to 2 mm, and the insulation layer may have a thickness of 2 to 3 mm.

A plurality of heater patterns may be provided, and the heater patterns may be provided in different areas of the heating plate, when viewed from a top.

The plurality of heater patterns may be connected to power supply lines that transmit electric power to the heater patterns, and the power supply lines may be inserted into one insertion hole formed in the insulation layer.

A radius of the heating plate may be larger than a diameter of the substrate supported in a plane aspect, and the insulation layer may have a diameter corresponding to the heating plate.

According to another aspect of the inventive concept, a substrate treating apparatus may include a process chamber having a treatment space, a support unit that supports a substrate in the treatment space, and a supply line that supplies a process gas including moisture into the treatment space, the support unit may include a heating plate having a diameter that is larger than a diameter of the substrate supported in a plane aspect, provided with a heater pattern on a lower surface thereof, and that heats the supported substrate, and an insulation layer having a diameter corresponding to the heating plate, covering the heater pattern and the lower surface of the heating plate, and including an epoxy molding compound, with respect to a total of 100 wt % of the epoxy molding compound of the insulation layer, the epoxy molding compound may include an inorganic filter of 65 to 88 wt %, an epoxy resin of 7 to 30 wt %, an epoxy resin hardener of 2 to 13 wt %, and an additive of 1.25 to 3 wt %, the inorganic filler may have particles of sizes of 2 to 30 μm, and may have, with respect to the inorganic filler of 100 wt %, 20 to 35 wt % of particles having an average particle diameter of 5 μm or less and 65 to 80 wt % of particles having an average particle diameter of more than 5 μm, the heating plate may have a thickness of 1 to 2 mm, and the insulation layer may have a thickness of 2 to 3 mm.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view schematically illustrating a substrate treating apparatus according to an embodiment of the inventive concept;

FIG. 2 is a cross-sectional view of the substrate treating apparatus that shows an application block or a development block of FIG. 1;

FIG. 3 is a plan view illustrating the substrate treating apparatus of FIG. 1;

FIG. 4 is a view illustrating an example of a hand of a transfer unit of FIG. 3;

FIG. 5 is a plan cross-sectional view schematically illustrating an example of a heat treatment chamber of FIG. 3;

FIG. 6 is a front cross-sectional view of the heat treatment chamber of FIG. 5;

FIG. 7 is a cross-sectional view illustrating the substrate treating apparatus provided in a heating unit of FIG. 6;

FIG. 8 is a view illustrating a heating plate of FIG. 7, when viewed from a bottom; and

FIG. 9 is an exploded perspective view illustrating states of the heating plate of a support unit of FIG. 7 and an insulation layer.

### DETAILED DESCRIPTION

Hereinafter, exemplary embodiments of the inventive concept will be described in more detail with reference to the accompanying drawings. The embodiments of the inventive may be modified in various forms, and the scope of the inventive concept should not be construed to be limited to the following embodiments. The embodiments of the inventive concept are provided to describe the present inventive for an ordinary person skilled in the art more completely. Accordingly, the shapes of the components of the drawings are exaggerated or reduced to emphasize clearer description thereof.

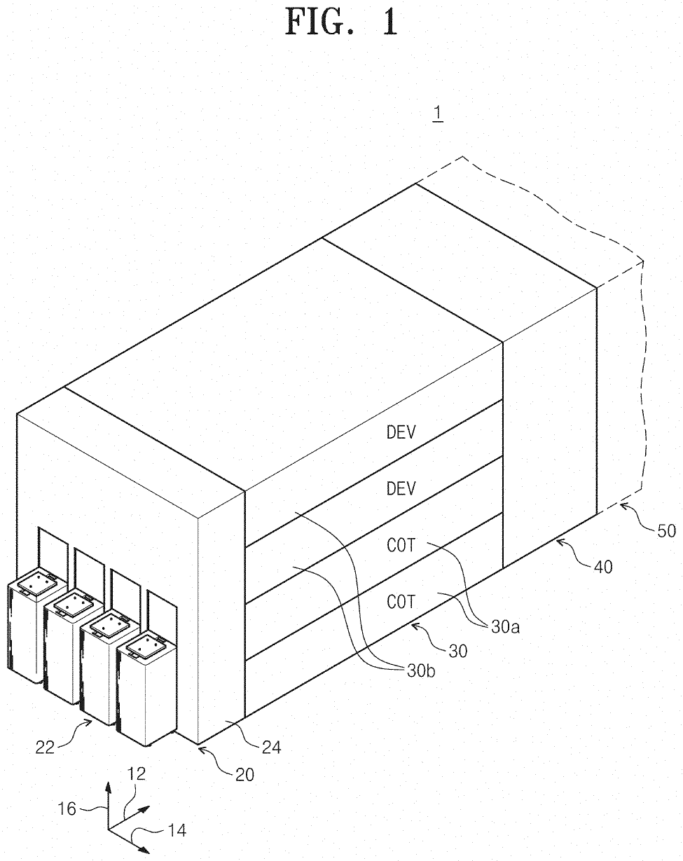

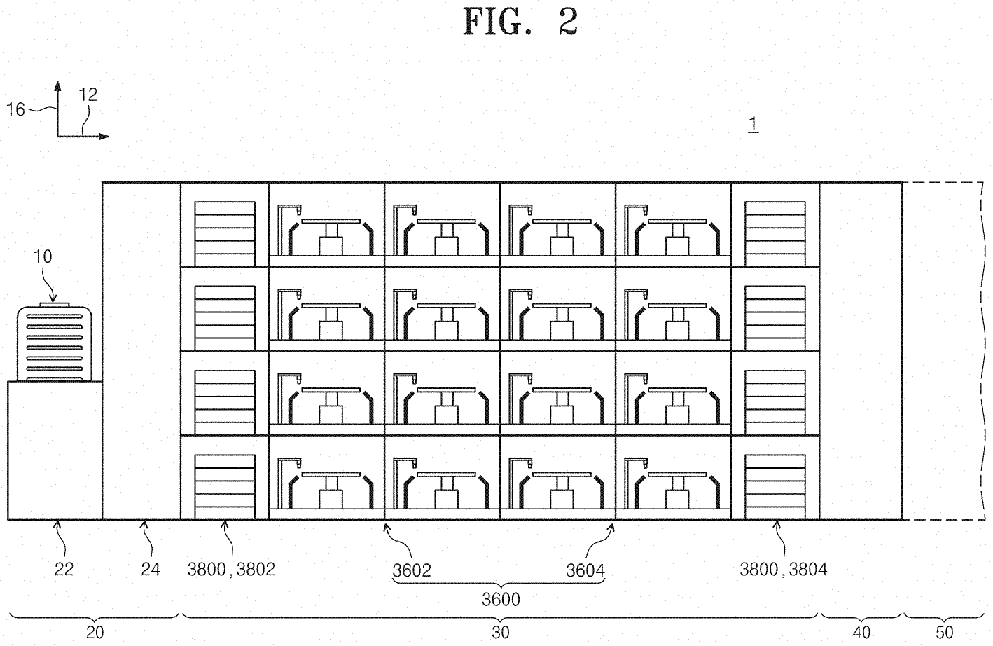

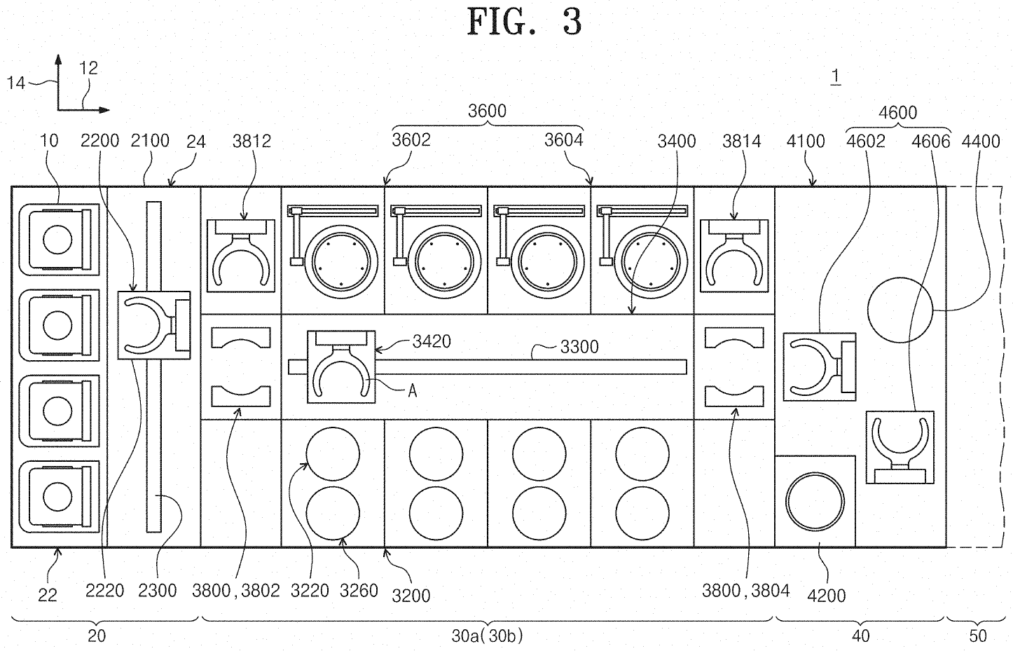

FIG. 1 is a view schematically illustrating a substrate treating apparatus according to an embodiment of the inventive concept. FIG. 2 is a cross-sectional view of the substrate treating apparatus that shows an application block or a development block of FIG. 1. FIG. 3 is a plan view illustrating the substrate treating apparatus of FIG. 1.

Referring to FIGS. 1 to 3, a substrate treating apparatus 1 includes an index module 20, a treatment module 30, and an interface module 40. According to an embodiment, the index module 20, the treatment module 30, and the interface module 40 are sequentially disposed in a row. Hereinafter, a direction, in which the index module 20, the treatment module 30, and the interface module 40 are arranged, will be referred to as an X axis direction 12, a direction that is perpendicular to the X axis direction 12 when viewed from the top will be referred to as a Y axis direction 14, and a direction that is perpendicular to both the X axis direction 12 and the Y axis direction 14 will be referred to as a Z axis direction 16.

The index module 20 transfers a substrate “W” from a container 10, in which the substrate “W” is received, to the treatment module 30, and the completely treated substrate “W” is received in the container 10. A lengthwise direction of the index module 20 is the Y axis direction 14. The index module 20 includes a plurality of load ports 22 and an index frame 24. The load ports 22 are located on an opposite side to the treatment module 30 with respect to the index frame 24. The containers 10, in which the substrates “W” are received, are positioned on the load port 22. A plurality of load ports 22 may be provided, and the plurality of load ports 22 may be disposed along the Y axis direction 14.

The container 10 may be the closed container 10 such as a front open unified pod (FOUP). The container 10 may be positioned on the load port 22 by a feeding unit (not illustrated) such as an overhead transfer, an overhead conveyor, or an automatic guided vehicle, or an operator.

An index robot 2200 is provided in an interior of the index frame 24. A guide rail 2300, a lengthwise direction of which is the Y axis direction 14, may be provided in the index frame 24, and the index robot 2200 may be movable on the guide rail 2300. The index robot 2200 includes a hand 2220, on which the substrate “W” is positioned, and the hand 2220 may be moved forwards and rearwards, be rotated about the Z axis direction 16, and be moved along the Z axis direction 16.

The treatment module 30 performs an application process and a development process on the substrate “W”. The treatment module 30 has an application block 30a and a development block 30b. The application block 30a performs the application process on the substrate “W”, and the development block 30b performs the development process on the substrate “W”. A plurality of application blocks 30a may be provided, and are stacked on each other. A plurality of development blocks 30b are provided, and the development blocks 30b are stacked on each other. According to the embodiment of FIG. 1, two application blocks 30a are provided and two development blocks 30b are provided. The application blocks 30a may be disposed below the development blocks 30b. According to an embodiment, the two application blocks 30a may perform the same process, and may have the same structure. Furthermore, the two development blocks 30a may perform the same process, and may have the same structure.

Referring to FIG. 3, the application block 30a has a heat treatment chamber 3200, a transfer chamber 3400, a liquid treatment chamber 3600, and a buffer chamber 3800. The heat treatment chamber 3200 performs a heat treatment process on the substrate “W”. The heat treatment process may include a cooling process and a heating process. The liquid treatment chamber 3600 may supply a liquid onto the substrate “W” and forms a liquid film. The liquid film may be a photoresist film or anti-reflection film. The photoresist film may be a photoresist film including a metallic material such as a metal oxide. The transfer chamber 3400 transfers the substrate “W” in the application block 30a between the heat treatment chamber 3200 and the liquid treatment chamber 3600.

The transfer chamber 3400 is provided such that a lengthwise direction thereof is in parallel to the X axis direction 12. A transfer unit 3420 is provided in the transfer chamber 3400. The transfer unit 3420 transfers the substrate between the heat treatment chamber 3200, the liquid treatment chamber 3600, and the buffer chamber 3800. According to an embodiment, the transfer unit 3420 has a hand “A”, on which the substrate “W” is positioned, and the hand “A” may be moved forwards and rearwards, be rotated about the Z axis direction 16, and be moved along the Z axis direction 16. A guide rail 3300, a lengthwise direction of which is parallel to the X axis direction 12, may be provided in the transfer chamber 3400, and the transfer unit 3420 may be movable on the guide rail 3300.

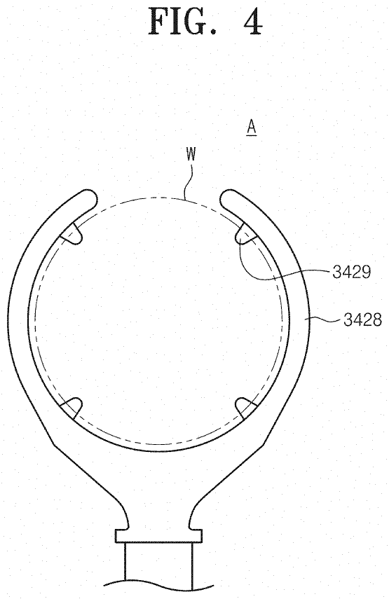

FIG. 4 is a view illustrating an example of a hand of a transfer unit of FIG. 3. Referring to FIG. 4, the hand “A” has a base 3428 and a support boss 3429. The base 3428 may have an annular ring shape, a circumferential portion of which is bent. The base 3428 has an inner diameter that is larger than a diameter of the substrate “W”. The support boss 3429 extends inwards from the base 3428. A plurality of support bosses 3429 are provided, and support an edge area of the substrate “W”. According to an example, four support bosses 3429 may be provided at an equal interval. It is preferable that the hand “A” of the transfer robot minimizes a contact area with the substrate “W”, and the hand “A” of the transfer robot may minimize contamination due to a contact between a lower surface of the substrate “W” and the hand “A” by minimizing the contact area with the substrate “W”.

Referring to FIGS. 2 and 3 again, a plurality of heat treatment chambers 3200 may be provided. The heat treatment chambers 3200 may be arranged along the X axis direction 12. The heat treatment chambers 3200 are located on one side of the transfer chamber 3400.

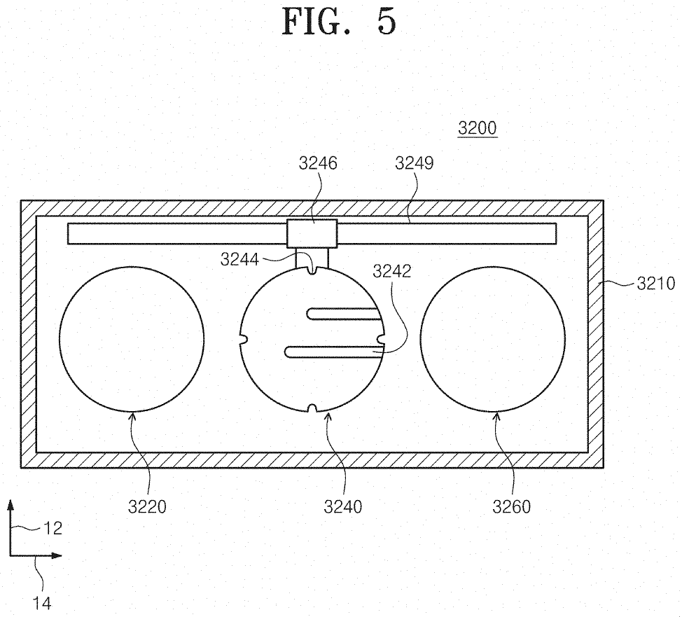

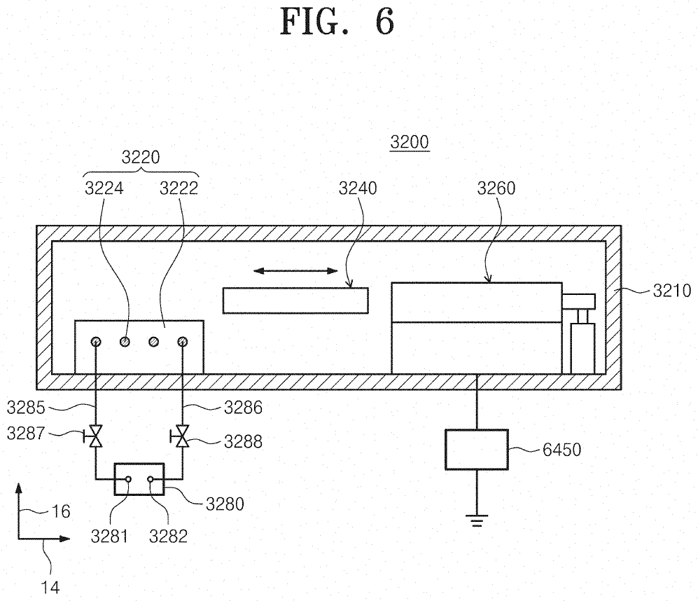

FIG. 5 is a plan cross-sectional view schematically illustrating an example of a heat treatment chamber of FIG. 3. FIG. 6 is a front cross-sectional view of the heat treatment chamber of FIG. 5. The heat treatment chamber 3200 may treat the substrate by heating the substrate or absorbing heat from the substrate. The heat treatment chamber 3200 may perform a heat treatment process on the substrate by heating the substrate or absorbing heat from the substrate. The heat treatment chamber 3200 includes a housing 3210, a cooling unit 3220, a transfer plate 3240, and a heating unit 3260.

The housing 3210 has a substantially rectangular parallelepiped shape. A transfer entrance (not illustrated), through which the substrate “W” is introduced and exits, is formed in a side wall of the housing 3210. The transfer entrance may maintain an opened state. Optionally, a door (not illustrated) may be provided to open and close the transfer entrance. The cooling unit 3220, the heating unit 3260, and the transfer plate 3240 are provided in the housing 3210. The cooling unit 3220 and the heating unit 3260 are provided side by side along the Y axis direction 14. According to an embodiment, the cooling unit 3220 may be located closer to the transfer chamber 3400 than the heating unit 3260.

The cooling unit 3220 may heat-treat the substrate “W”. The cooling unit 3220 may heat-treat the substrate “W” by absorbing heat from the substrate “W” (by transferring cool air to the substrate). The cooling unit 3220 may include a chiller plate 3222. The chiller plate 3222 may support the substrate “W”. The chiller plate 3222 may have a seating surface that supports the substrate “W”. A cooling channel 3224 may be formed in an interior of the chiller plate 3222. The cooling channel 3224 may be a passage, through which a cooling fluid flows. The cooling fluid that flows through the cooling channel 3224 may be cooling water. One end of the cooling channel 3224 may be connected to a first supply line 3285. An opposite end of the cooling channel 3224 may be connected to a first recovery line 3286.

A refrigerant supply source 3280 may store the cooling fluid. The refrigerant supply source 3280 may supply the cooling fluid to the cooling unit 3220. Furthermore, the refrigerant supply source 3280 may recover the cooling fluid from the cooling unit 3220. The cooling fluid supplied and/or recovered by the refrigerant supply source 3280 may be cooling water. However, the present disclosure is not limited thereto, but the cooling fluid may be a cooling gas.

The refrigerant supply source 3280 may include a refrigerant supply hole 3281 and a refrigerant recovery hole 3282. The cooling fluid may be supplied through the refrigerant supply hole 3281. The cooling fluid may be supplied to the cooling channel 3224 through the refrigerant supply hole 3281. The refrigerant supply hole 3281 may be connected to the first supply line 3285. The cooling fluid may be supplied to the cooling channel 3224 through the refrigerant supply hole 3281 via the first supply line 3285. A first supply valve 3287 may be installed in the first supply line 3285. The first supply valve 3287 may be an on/off valve. However, the present disclosure is not limited thereto, but the first supply valve 3287 may be a flow rate adjusting valve.

Further, the refrigerant recovery hole 3282 may recover the cooling fluid. The refrigerant recovery hole 3282 may recover the cooling fluid supplied to the cooling channel 3224. The refrigerant recovery hole 3282 may be connected to the first recovery line 3286. The cooling fluid supplied to the cooling channel 3224 may be recovered through the refrigerant recovery hole 3282 via the first recovery line 3286. For example, the refrigerant recovery hole 3282 may recover the supplied cooling fluid by reducing a pressure of the cooling channel 3224 by the medium of the first recovery line 3286. A first recovery valve 3288 may be installed in the first recovery line 3286. The first recovery valve 3288 may be an on/off valve. However, the present disclosure is not limited thereto, but the first recovery valve 3288 may be a flow rate adjusting valve.

The transfer plate 3240 has a substantially disk shape, and has a diameter corresponding to the substrate “W”. A notch 3244 is formed at an edge of the transfer plate 3240. The notch 3244 may have a shape corresponding to the boss 3429 formed in the hand “A” of the above-described transfer robot 3420. Further, the number of the notches 3244 is the number corresponding to the bosses 3429 formed in the hand “A”, and the notches 3244 are formed at locations corresponding to the bosses 3429. When the upward/downward locations of the hand “A” and the transfer plate 3240 are changed in a state, in which the hand “A” and the transfer plate 3240 are arranged in upward/downward directions, the substrate “W” is transferred between the hand “A” and the transfer plate 3240. The transfer plate 3240 is mounted on a guide rail 3249, and is moved along the guide rail 3249 by a driver 3246. A plurality of slit-shaped guide grooves 3242 are provided in the transfer plate 3240. The guide grooves 3242 extend from an end of the transfer plate 3240 to an interior of the transfer plate 3240. Lengthwise directions of the guide grooves 3242 are provided along the Y axis direction 14, and the guide grooves 3242 are located to be spaced apart from each other along the X axis direction 12. The guide grooves 3242 prevent the transfer plate 3240 and the lift pin from interfering with each other when the substrate “W” is delivered between the transfer plate 3240 and the heating unit 3260.

The heating unit 3260 may treat the substrate “W” by transferring heat to the substrate “W”.

The heating units 3260 provided to some of the heat treatment chambers 3200 may improve an attachment force between the photoresist and the substrate “W” by supplying gas while the substrate “W” is heated. The gas may be a hydrophobic gas that makes the substrate “W” hydrophobic. According to an embodiment, the gas may be a hexamethyldisilane gas.

Furthermore, the heating units 3260 provided to others of the heat treatment chambers 3200 may perform a baking process by heating the substrate “W”. For example, the heating units 3260 provided to the others of the heat treatment chambers 3200 may perform a heat treatment by heating the substrate “W” In operations before and after an exposure process is performed. Hereinafter, among the heating units 3260, the heating units 3260 that perform the baking process by heating the substrate “W” will be described as an example. The heating unit 3260 according to the embodiment of the inventive concept is an apparatus that performs the baking process on the substrate “W”, on which the photoresist film including a metal is formed.

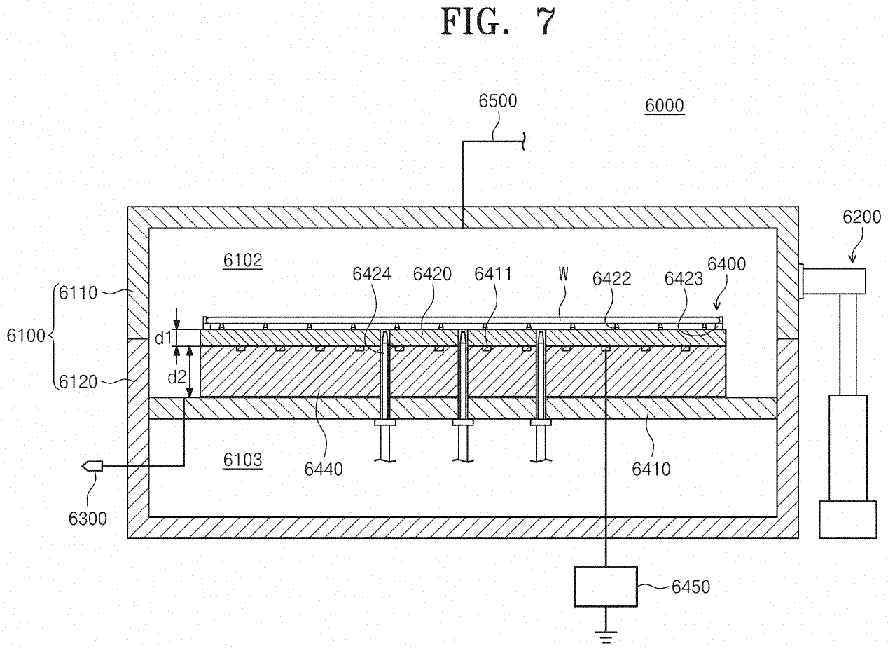

FIG. 7 is a cross-sectional view illustrating the substrate treating apparatus provided in a heating unit of FIG. 6. Referring to FIG. 7, a substrate treating apparatus 6000 provided to the heating unit 3260 may include a process chamber 6100, a driver 6200, an exhaustion line 6300, a support unit 6400, and a supply line 6500.

A treatment space 6102 is provided in an interior of the process chamber 6100. The process chamber 6100 may include an upper chamber 6110 and a lower chamber 6120. The upper chamber 6110 may be circular when viewed from a top. The upper chamber 6110 may have a vessel shape, a lower side of which is opened. The upper chamber 6110 may have a cylindrical shape, a lower side of which is opened. The lower chamber 6120 may be disposed below the upper chamber 6110. The lower chamber 6120 may be circular when viewed from a top. The lower chamber 6120 may have a vessel shape, an upper side of which is opened. When viewed from a top, the upper chamber 6110 and the lower chamber 6120 may have the same diameter. The upper chamber 6110 and the lower chamber 6120 may be combined to form the treatment space 6102. Furthermore, a sealing member (not illustrated) may be provided between the upper chamber 6110 and the lower chamber 6120 to close the treatment space 6102 more tightly.

The driver 6200 may open or close the treatment space 6102 included in the process chamber 6100. The driver 6200 may be coupled to any one of the upper chamber 6110 and the lower chamber 6120. For example, the driver 6200 may be coupled to the upper chamber 6110. The driver 6200 coupled to the upper chamber 6110 may elevate the upper chamber 6110 upwards and downwards. The driver 6200 may raise the upper chamber 6110 to open the treatment space 6102 when the substrate “W” is carried into the treatment space 6102. Furthermore, the driver 6200 may cause the upper chamber 6110 and the lower chamber 6120 to contact each other to close the treatment space 6102 while the process of treating the substrate “W” is performed. Although it has been described as an example that the driver 6200 is coupled to the upper chamber 6110 in the above-described example, but the inventive concept is not limited thereto but the driver 6200 may be coupled to the lower chamber 6120 to elevate the lower chamber 6120.

The exhaustion line 6300 may exhaust an atmosphere of the treatment space 6102. For example, the exhaustion line 6300 may exhaust side-products, such as particles, which are generated while the substrate “W” is treated in the treatment space 6102 to the outside. The exhaustion line 6300 may be connected to the process chamber 6100. The exhaustion line 6300 may be coupled to any one of the upper chamber 6110 and the lower chamber 6120. For example, the exhaustion line 6300 may be connected to a partition wall 6410 that supports the support unit 6400 while passing through the lower chamber 6120. The exhaustion line 6300 may be provided to a lower portion of the support unit 6400 to exhaust the atmosphere of the treatment space 6102.

The supply line 6500 may supply mist to the treatment space 6102 as the process gas. As an example, the mist may be moisture. The supply line 6500 may be connected to the process chamber 6100. As an example, the supply line 6500 may be connected to any one of the upper chamber 6110 and the lower chamber 6120. A humidity in the interior of the treatment space 6102 may be raised to about 70% or more by the mist supplied to the treatment space 6102.

The partition wall 6410 may be provided in the process chamber 6100. As an example, the partition wall 6410 may be provided to the lower chamber 6120, and may be installed horizontally at a location that is spaced apart from a bottom surface of the lower chamber 6120. The partition wall 6410 separates the space in the interior of the process chamber 6100 upwards and downwards, the treatment space 6102 is formed on an upper side of the partition wall 6410 and a lower space 6103 is formed on a lower side of the partition wall 6410. The treatment space 6102 may be provided as a space for treating the substrate “W”, and configurations, such as an elevation module (not illustrate) that elevates a lift pin 6424 or a power supply line, may be preserved in the lower space 6103.

The support unit 6400 may be supported by an upper surface of the partition wall 6410. The support unit 6400 may support the substrate “W” in the treatment space 6102. The support unit 6400 may include a heating plate 6420 and a heater power source 6450. The heating plate 6420 may heat the supported substrate “W”. The heating plate 6420 may have a plate shape when viewed from a top. As an example, the heating plate 6420 may have a disk shape when viewed from a top.

The heating plate 6420 may support the substrate “W”. For example, a support pin 6422 and a guide pin 6423 may be provided on the heating plate 6420. Furthermore, the heating plate 6420 may support the substrate “W” by the medium of the support pin 6422 and the guide pin 6423. A plurality of support pins 6422 may be provided. The support pin 6422 may support the lower surface of the substrate “W”. The support pin 6422 may space the lower surface of the substrate “W” and an upper surface of the heating plate 6420 apart from each other by a specific interval. The specific interval may be a unit of several or several tens of micrometers (m). The support pin 6422 may prevent contamination due to a contact of the heating plate 6420 and the lower surface of the substrate “W” by spacing the lower surface of the substrate “W” and the upper surface of the heating plate 6420 apart from each other by the specific interval. However, because heat transfer rate may decrease as the support pin 6422 is higher, the lower surface of the substrate “W” and the upper surface of the heating plate 6420 are set to be spaced apart from each other at a proper interval, by which the heat transfer efficiency of the support pin 6422 may be achieved and contamination may be prevented. The guide pin 6423 may support the lower surface and sides of the substrate “W”. The guide pin 6423 helps the substrate “W” be positioned on the support unit 6400 at a proper location. The guide pin 6423 may prevent the substrate “W” from being separated from the support unit 6400 even though heat is transferred to the substrate “W” and the substrate “W” is thermally changed. FIG. 7 illustrates that a support surface that supports the lower surface of the substrate “W” of the guide pin 6423 and a protruding surface that supports the side of the substrate “W” are perpendicular to each other, but the inventive concept is not limited thereto. For example, the protruding surface that supports the side of the substrate “W” may be provided to be inclined upwards as it goes to the outer side along a radial direction of the heating plate 6420. Accordingly, even when the substrate “W” is positioned on the support unit 6400 rather inaccurately, the substrate “W” may be positioned on the support unit 6400 at a proper location. Furthermore, a lift pin hole 6425 may be formed in the heating plate 6420. A plurality of lift pin holes 6425 may be provided. The lift pin holes 6425 may be spaced apart from each other along a circumferential direction of the heating plate 6420 when viewed from a top. The lift pins 6424 may be inserted into the lift pin holes 6425. The lift pins 6424 may support the lower surface of the substrate “W”, and may move the substrate “W” upwards and downwards.

The heating plate 6420 may be formed of a thermally conductive material. For example, the heating plate 6420 may be formed of a material including a metal. Unlike this, the heating plate 6420 may be formed of a material including ceramics. As an example, the heating plate 6420 may be formed of an aluminum nitride (AlN) material. In another embodiment, the heating plate 6420 may be SiC or Al₂O₃. A heater pattern 6411 may be formed on the lower surface of the heating plate 6420. The heater pattern 6411 may be connected to the heater power source 6450. The heater pattern 6411 may emit heat by using electric power applied by the heater power source 6450. The heater pattern 6411 may be formed of an Ag-based material. The heater pattern 6411 may be formed in a printing scheme by using paste of an Ag-based material. The heater pattern 6411 is electrically connected to the heater power source 6450. The heater pattern 6411 may emit heat as the heater power source 6450 applies electric power to the heater pattern 6411.

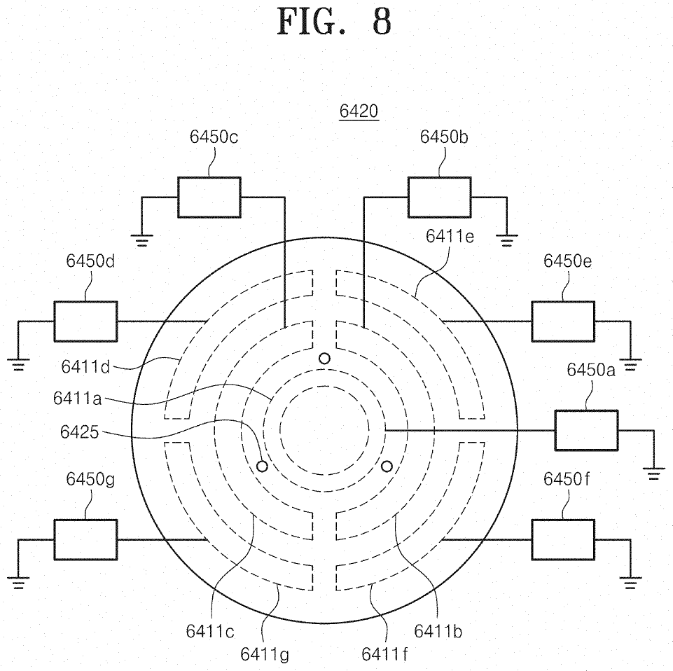

FIG. 8 is a view illustrating a heating plate of FIG. 7, when viewed from a bottom. Referring to FIG. 8, a plurality of heater patterns 6411 may be provided on the lower surface of the heating plate 6420. The plurality of heater patterns 6411 may adjust temperatures of different area of the substrate “W”, which are viewed from a top. The plurality of heater patterns 6411 may adjust temperatures of different area of the substrate “W”, which are viewed from a top. Furthermore, the plurality of heater patterns 6411 may be independently controlled. For example, the heater patterns 6411 may include a first heater pattern 6411a, a second heater pattern 6411b, a third heater pattern 6411c, a fourth heater pattern 6411d, a fifth heater pattern 6411e, a sixth heater pattern 6411f, and a seventh heater pattern 6411g. For example, the heater power sources 6450 may include a first heater power source 6450a, a second heater power source 6450b, a third heater power source 6450c, a fourth heater power source 6450d, a fifth heater power source 6450e, a sixth power source 6450f, and a seventh heater power source 6450g. Further, the first heater pattern 6411a, the second heater pattern 6411b, the third heater pattern 6411c, the fourth heater pattern 6411d, the fifth heater pattern 6411e, the sixth heater pattern 6411f, and the seventh heater pattern 6411g may be connected to the first heater power source 6450a, the second heater power source 6450b, the third heater power source 6450c, the fourth heater power source 6450d, the fifth heater power source 6450e, the sixth power source 6450f, and the seventh heater power source 6450g, respectively. That is, the heat transferred to the substrate “W” may be independently controlled according to the area of the substrate “W” viewed from the top, by independently controlling the electric power delivered to the plurality of heater patterns 6411.

Referring to FIG. 7 again, an insulation layer 6440 may be provided on the lower surface of the heating plate 6420. The insulation layer 6440 may be provided to cover the lower surface of the heating plate 6420. The insulation layer 6440 may be provided to cover the heater patterns 6411. In more detail, the insulation layer 6440 may be provided to cover the lower surface of the heating plate 6420 and the heater patterns 6411.

The insulation layer 6440 may be formed to be applied to the lower surface of the heating plate 6420 and the heater patterns 6411. The insulation layer 6440 may be formed of a material including a resin. The insulation layer 6440 may be formed of a thermosetting resin. Here, the thermosetting resin may include epoxy. For example, the insulation layer 6440 may be formed of a material including an epoxy molding compound. The insulation layer 6440 may be formed of a material including an epoxy molding compound having an excellent thermal conductivity. The insulation layer 6440 formed of a material including an epoxy molding compound may product the heater patterns 6411 from external environments, such as moisture, impacts, and electric charges.

The epoxy molding compound may have a composition as in Table 1.

TABLE 1
Composition of Epoxy Molding Compound according
to Embodiment of Inventive Concept

| Number | Materials | Contents (wt %) |
|---|---|---|
| 1 | Inorganic Filler | 65 to 88 |
| 2 | Epoxy resin | 7 to 30 |
| 3 | Epoxy resin hardener | 2 to 13 |
| 4 | Additive | 1.25 to 3 |

| | |
|---|---|
| Total | 100 |

The inorganic filler may occupy 65 to 88 wt % of the entire composition of the epoxy molding compound. The inorganic filler may be AlN, SiO₂, Al₂O₃, or SiC. The inorganic filler may be particles having sizes of 2 to 30 μm. An average particle diameter of the inorganic filler may be more than 5 μm, and the particles, most of which have irregular shapes, may occupy 65 to 80 wt % of the total weight of the inorganic filler. An average particle diameter of the inorganic filler may be not more than 5 μm, and the fused particles, most of which have irregular shapes and have spherical shapes, may occupy 20 to 35 wt % of the total weight of the inorganic filler. When the inorganic filler includes many particles, an average particle diameter of which is relatively large. When the particles, an average diameter of which is relatively large, occupy 20 to 35 wt % of the weight of the inorganic filler, the physical characteristics of the inorganic filler particularly become excellent. The inorganic filler may reduce thermal stresses generated through thermal expansion of polymers, and it is preferable that the inorganic filler occupies 65% or more of the composition of the epoxy molding compound.

The epoxy resin may occupy 7 to 30 wt % of the entire composition of the epoxy molding compound. According to an embodiment, the epoxy resin may be a novolac epoxy resin or a bisphenol A type epoxy resin. According to another experiment of the embodiment of the inventive concept, the epoxy resin is a novolac epoxy resin,

The epoxy resin hardener may occupy 2 to 13 wt % of the entire composition of the epoxy molding compound. According to an experiment of the embodiment of the inventive concept, the epoxy resin hardener may be a phenol novolac hardener.

The additive may occupy 1.25 to 3 wt % of the entire composition of the epoxy molding compound. The additive may include a catalyst, a mold release agent, a coupling agent, and/or a stress relief agent. According to the embodiment, the catalyst may occupy 0.75 to 1 wt % of the entire composition of the epoxy molding compound, the mold release agent may occupy 0 to 0.5 wt % of the entire composition of the epoxy molding compound, the coupling agent may occupy 0.5 to 1 wt % of the entire composition of the epoxy molding compound, and the stress relief agent may occupy 0 to 0.5 wt % of the entire composition of the epoxy molding compound. As an insulation layer 6430 covers and protects the heater patterns 6411, an ECM that may be generated in the heater patterns 6411 that are vulnerable to moisture or a humid environment may be prevented.

Furthermore, the insulation layer 6440 may have one insertion hole. A plurality of power supply lines that connect the plurality of heater patterns 6411 and the plurality of power sources 6450, which have been described above, may be inserted into the insertion hole. The plurality of heater patterns 6411 and the plurality of power sources 6450 may be connected to each other through a daisy chain scheme. Accordingly, the power supply lines may be arranged more effectively, and the power supply lines may be minimized from being exposed.

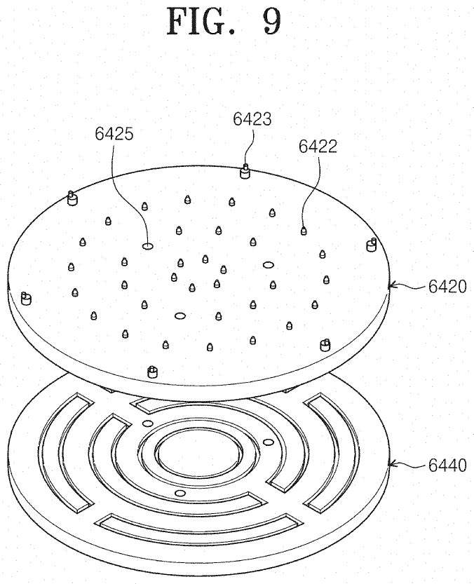

FIG. 9 is an exploded perspective view illustrating states of the heating plate of the support unit of FIG. 7 and the insulation layer. Referring to FIG. 9, a heating plate provided in a general substrate treating apparatus is thick. When the thickness of the heating plate is thin, the heating plate may be bent or brittle-fractured. However, according to the embodiment of the inventive concept, the insulation layer 6440 may be provided on the lower surface of the heating plate 6420. The insulation layer 6440 may be formed of a material including an epoxy molding compound. The insulation layer 6440 may be formed of a material including an epoxy molding compound having an excellent thermal conductivity. That is, because the insulation layer 6440 is provided on the lower surface of the heating plate 6420, the heating plate 6420 may be minimized from being thermally deformed, being bent, or being fractured even though the heating plate 6420 is very thin. That is, the thickness of the heating plate 6420 may be remarkably reduced by providing the insulation layer 6440. According to an embodiment, the thickness d1 of the heating plate 6420 may be 2 mm or less. Furthermore, the thickness d2 of the insulation layer 6440 may be 2 mm or more. In a more detailed example, the thickness d1 of the heating plate 6420 may be 1 mm. Furthermore, the thickness d2 of the insulation layer 6440 may be 3 mm. When the thickness d1 of the heating plate 6420 is small, temperature uniformity may be increased.

Furthermore, the insulation layer 6440 may be directly coupled to various components. Because the insulation layer 6440 is formed of a material including an epoxy molding compound, it is possible to form a coupling hole in the insulation layer 6440 itself. In an embodiment, the coupling hole may be formed through laser drilling. When the coupling hole is formed in the insulation layer 6440 itself, the insulation layer 6440 may be coupled to various components through a coupling means, such as a screw or a bolt. Then, the coupling means may be inserted into at least one coupling hole formed in the insulation layer 6440.

Referring to FIGS. 2 and 3 again, a plurality of buffer chambers 3800 are provided. Some of the buffer chambers 3800 are disposed between the index module 20 and the transfer chamber 3400. Hereinafter, such buffers will be referred to as front buffers 3802. A plurality of front buffers 3802 are provided, and are stacked on each other along an upward/downward direction. Other of the buffer chambers 3802 and 3804 are disposed between the transfer chamber 3400 and the interface module 40. Hereinafter, such buffer chambers will be referred to as rear buffers 3804. A plurality of rear buffers 3804 are provided, and are stacked on each other along an upward/downward direction. The front buffers 3802 and the rear buffers 3804 temporarily preserve a plurality of substrate “W”. The substrates “W” preserved in the front buffers 3802 are carried in or out by the index robot 2200 and the transfer robot 3420. The substrates “W” preserved in the rear buffers 3804 are carried in or out by the transfer robot 3420 and a first robot 4602.

The development block 30b has the heat treatment chamber 3200, the transfer chamber 3400, and the liquid treatment chamber 3600. The heat treatment chamber 3200, the transfer chamber 3400, and the liquid treatment chamber 3600 of the development block 30b have structures and arrangements that are substantially similar to those of the heat treatment chamber 3200, the transfer chamber 3400, and the liquid treatment chamber 3600 of the application block 30a, and thus a description thereof will be omitted. However, in the development block 30b, all of the liquid treatment chambers 3600 supply a development liquid in the same way and provide the development liquid into the development chamber 3600 that develop the substrate.

The interface module 40 connects the treatment module 30 to an external exposure apparatus 50. The interface module 40 has an interface frame 4100, an additional process chamber 4200, an interface buffer 4400, and a transfer member 4600.

A fan filter unit that forms downward flows in an interior thereof may be provided at an upper end of the interface frame 4100. The additional process chamber 4200, the interface buffer 4400, and the transfer member 4600 are disposed in an interior of the interface frame 4100. The additional process chamber 4200 may perform a specific additional process before the substrate “W”, on which a process has been performed in the application block 30a, is carried into the exposure apparatus 50. Optionally, the additional process chamber 4200 may perform a specific additional process before the substrate “W”, on which a process has been performed in the exposure apparatus 50-, is carried into the development block 30b. According to an example, the additional process may be an edge exposing process of exposing an edge area of the substrate “W”, an upper surface cleaning process of cleaning an upper surface of the substrate “W”, or a lower surface cleaning process of cleaning a lower surface of the substrate “W”. A plurality of additional process chambers 4200 may be provided, and may be stacked on each other. All of the additional process chambers 4200 may perform the same process. Optionally, some of the additional process chambers 4200 may perform different processes.

The interface buffer 4400 provides a space, in which the substrate “W” that is transferred between the application block 30a, the additional process chambers 4200, the exposure apparatus 50, and the development block 30b temporarily stays while being transferred. A plurality of interface buffers 4400 may be provided, and the plurality of interface buffers 4400 may be stacked on each other.

According to an embodiment, the additional process chambers 4200 may be disposed on one surface of the transfer chamber 3400 with respect an extension line in a lengthwise direction of the transfer chamber 3400, and the interface buffers 4400 may be disposed on another side surface of the transfer chamber 3400.

The transfer member 4600 transfers the substrate “W” between the application block 30a, the additional process chambers 4200, the exposure apparatus 50, and the development block 30b. The transfer member 4600 may be one or a plurality of robots. According to an example, the transfer member 4600 has the first robot 4602 and a second robot 4606. The first robot 4602 may transfer the substrate “W” between the application block 30a, the additional process chamber 4200, and the interface buffer 4400, the interface robot 4606 may transfer the substrate “W” between the interface buffer 4400 and the exposure apparatus 50, and the second robot 4604 may transfer the substrate “W” between the interface buffer 4400 and the development block 30b.

The first robot 4602 and the second robot 4606 include hands, on which the substrates “W” are positioned, respectively, and the hands may be moved forwards and rearwards, may be rotated about an axis that is parallel to the Z axis direction 16, and may be moved along the Z axis direction 16.

According to an embodiment of the inventive concept, the substrate may be efficiently treated.

Furthermore, according to an embodiment of the inventive concept, an ECM due to a humid environment may be prevented in a support unit of a heating unit provided in a substrate treating apparatus.

Furthermore, according to an embodiment of the inventive concept, bases of a support unit of a heating unit provided in a substrate treating apparatus may obtain excellent mechanical characteristics at a preset thickness.

Furthermore, according to an embodiment of the inventive concept, a heating plate may be minimized from being deflected due to heat.

The effects of the inventive concept are not limited to the above-mentioned effects, and the unmentioned effects can be clearly understood by those skilled in the art to which the inventive concept pertains from the specification and the accompanying drawings.

The above detailed description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

1. A substrate treating apparatus comprising:
a process chamber having a treatment space;
a support unit configured to support a substrate in the treatment space; and
a supply line configured to supply a process gas into the treatment space,
wherein the support unit includes:
a heating plate provided with a heater pattern on a lower surface thereof and configured to heat the supported substrate; and
an insulation layer covering the heater pattern and the lower surface of the heating plate.

2. The substrate treating apparatus of claim 1, wherein the process gas includes moisture.

3. The substrate treating apparatus of claim 1, wherein the insulation layer is formed of a material including a thermosetting resin.

4. The substrate treating apparatus of claim 3, wherein the thermosetting resin includes epoxy.

5. The substrate treating apparatus of claim 1, wherein the insulation layer is formed of an epoxy molding compound.

6. The substrate treating apparatus of claim 5, wherein the epoxy molding compound includes:
with respect to a total of 100 wt %,
an inorganic filter of 65 to 88 wt %;
an epoxy resin of 7 to 30 wt %;
an epoxy resin hardener of 2 to 13 wt %; and
an additive of 1.25 to 3 wt %.

7. The substrate treating apparatus of claim 5, wherein the epoxy molding compound includes, with respect to a total of 100 wt %, an inorganic filler of 65 to 88 wt %, and
wherein the inorganic filler has particles of sizes of 2 to 30 μm, and has, with respect to the inorganic filler of 100 wt %, 20 to 35 wt % of particles having an average particle diameter of 5 μm or less and 65 to 80 wt % of particles having an average particle diameter of more than 5 μm.

8. The substrate treating apparatus of claim 7, wherein in the inorganic filler, the particles of the average diameter of 5 μm or less have spherical shapes, and the particles of the average diameter of more than 5 μm have irregular shapes.

9. The substrate treating apparatus of claim 1, wherein the heating plate has a thickness of 1 to 2 mm, and
wherein the insulation layer has a thickness of 2 to 3 mm.

10. The substrate treating apparatus of claim 1, wherein a plurality of heater patterns are provided, and
wherein the heater patterns are provided in different areas of the heating plate, when viewed from a top.

11. The substrate treating apparatus of claim 10, wherein the plurality of heater patterns are connected to power supply lines that transmit electric power to the heater patterns, and
wherein the power supply lines are inserted into one insertion hole formed in the insulation layer.

12. The substrate treating apparatus of claim 1, wherein a radius of the heating plate is larger than a diameter of the substrate supported in a plane aspect, and
wherein the insulation layer has a diameter corresponding to the heating plate.

13. A substrate treating apparatus comprising:
a process chamber having a treatment space;
a support unit configured to support a substrate in the treatment space; and
a supply line configured to supply a process gas including moisture into the treatment space,
wherein the support unit includes:
a heating plate having a diameter that is larger than a diameter of the substrate supported in a plane aspect, provided with a heater pattern on a lower surface thereof, and configured to heat the supported substrate; and
an insulation layer having a diameter corresponding to the heating plate, covering the heater pattern and the lower surface of the heating plate, and including an epoxy molding compound,
wherein, with respect to a total of 100 wt % of the epoxy molding compound of the insulation layer, the epoxy molding compound includes:
an inorganic filter of 65 to 88 wt %;
an epoxy resin of 7 to 30 wt %;
an epoxy resin hardener of 2 to 13 wt %; and
an additive of 1.25 to 3 wt %,
wherein the inorganic filler has particles of sizes of 2 to 30 μm, and has, with respect to the inorganic filler of 100 wt %, 20 to 35 wt % of particles having an average particle diameter of 5 μm or less and 65 to 80 wt % of particles having an average particle diameter of more than 5 μm,
wherein the heating plate has a thickness of 1 to 2 mm, and
wherein the insulation layer has a thickness of 2 to 3 mm.
